(19) United States
(12) Patent Application Publication
(10) Pub. No.: US 2024/0395984 A1
(43) Pub. Date: Nov. 28, 2024

(54) OPTOELECTRONIC COMPONENT AND METHOD FOR ITS MANUFACTURE

(71) Applicant: AMS-OSRAM INTERNATIONAL GMBH, Regensburg (DE)

(72) Inventors: Daniel Richter, Abbach (DE); Gunnar Petersen, Regensburg (DE); Simon Schwalenberg, Brennberg (DE)

(21) Appl. No.: 18/689,760

(22) PCT Filed: Sep. 7, 2022
(86) PCT No.: PCT/EP2022/074923

§ 371 Date: Mar. 6, 2024

(30) Foreign Application Priority Data
Sep. 9, 2021 (DE) 10 2021 123 410.7

(51) Int. Cl. H01L 33/50

(52) U.S. Cl. CPC H01L 33/508; H01L 2933/0041

(57) ABSTRACT

In an embodiment an optoelectronic component includes at least one semiconductor component configured to emit light of a first wavelength through a surface and a converter layer arranged on the surface of the at least one semiconductor component, the converter layer configured to convert the light of the first wavelength into light of a second wavelength, wherein a portion of the converter layer comprises a wavelength-selective mirror for a range of the first wavelength.

### CROSS-REFERENCE TO RELATED APPLICATIONS

This patent application is a national phase filing under section 371 of PCT/EP2022/074923, filed Sep. 7, 2022, which claims the priority of German patent application 10 2021 123 410.7, filed Sep. 9, 2021, each of which is incorporated herein by reference in its entirety.

### TECHNICAL FIELD

The present invention relates to an optoelectronic component with at least one light-emitting semiconductor component which is provided with a converter layer on a light-emitting surface, and to a method of manufacturing such a component.

### BACKGROUND

In LED components that produce white light in the eye of the beholder, part of the light from a blue LED chip is classically converted to longer wavelengths (yellow) via a phosphor conversion element. The combination of blue and yellow light thus gives the impression of white light.

In the manufacture of such components, semiconductor components are usually produced at wafer level and then covered with a conversion layer. Known techniques are used for this, which can lead to various disadvantages and shortcomings depending on the approach and process used.

The prior art includes, for example, wafer level conversion by the homogeneous application of phosphorus or a matrix material layer with converter material, e.g. by means of spray coating.

The approaches described for such an LED are cost-intensive, as the wavelength distribution of the processed blue LED wafer in combination with the conversion element can produce a very broad color location distribution without further color location control. This can be caused, for example, by a different thickness of the conversion material. However, as only a very narrow color location range (bin) is desired in practice, either a high level of waste is produced or a great deal of effort must be invested in sorting and combining LED chips and conversion elements in a targeted manner. Both are cost-intensive.

### SUMMARY

Embodiments provide a more cost-effective light-emitting component and a more cost-effective method for manufacturing a light-emitting component with a defined color location.

The inventors have recognized that chromaticity shift can also be achieved by means of an additional wavelength-selective mirror above the converter material, which covers only a portion of the converter surface. In other words, some of the unconverted light generated by a semiconductor component is reflected back into the converter material by the mirror, while converted light is essentially transmitted. The reflected unconverted light can react again in the converter material. In this way, the proportion of converted to unconverted light can be changed using the degree of coverage of the converter surface with a wavelength-selective mirror or reflector, thereby shifting the color location.

Surprisingly, it was found that even a very low degree of opacity of a few % can result in a significant shift of several 10 points (in the range of up to 70 points or even more) on the CIE color standard table without having to accept any major loss of brightness. The latter is caused by shading, but is within a range of less than 20%, in particular usually less than 10%. Accordingly, the yield or the yield of components on a wafer is considerably increased in this way. In addition, the proposed measures can be partially carried out in a reactor and therefore generally require fewer transfer steps, which reduces costs.

The above-mentioned problem is solved in particular by an optoelectronic component having at least one semiconductor component which is configured to emit light of a first wavelength through a surface. A converter layer for converting light of the first wavelength into light of a second wavelength is arranged on the surface, a portion of the converter layer being provided with a mirror which is wavelength-selective for the range of the first wavelength.

The ratio between converted light and non-converted light can be influenced by (partially) applying a wavelength-selective mirror, for example in the form of a DBR mirror, to the top of the converter for the range of the first wavelength. In the area covered with DBR, a higher proportion of blue light (converter pump WL) is reflected back and can be absorbed and converted by the conversion system with a certain probability. If a small or no area is covered with a suitable DBR, a high and constant blue component is retained.

The term “component emitting light of a first wavelength” means that the component emits light in a narrowly defined spectrum whose maximum corresponds to the first wavelength. A light-emitting diode is such a component, as its spectrum is clearly limited in contrast to filaments, for example. The term “wavelength-selective mirror” or reflector should be interpreted in the same way. This shows a high reflectivity in a certain range, which decreases with a certain gradient outside this range. The steeper this gradient is, the greater its selectivity.

In some aspects of the proposed principle, the wavelength selective mirror is provided as at least one reflector strip, or a plurality of parallel reflector strips, on the converter material of the converter layer. The reflector strip may be formed as a distributed Bragg reflector or other wavelength selective element.

The number of strips can be greater than 3, and in particular 6 to 9. The thickness of the individual strips can be the same. However, it is also possible to use different thicknesses if this appears appropriate for the overall radiation characteristics. As there is often an increased defect density or converter edges in the edge area of optoelectronic semiconductor components, it may be advisable not to provide a reflector strip here.

The distance between the strips can also be the same or different. In some aspects, the wavelength-selective mirror is applied in the form of several parallel reflector strips and several reflector strips running perpendicular to these reflector strips. These thus create a checkerboard pattern. Accordingly, in some aspects, rectangles, squares or other shapes may be provided as wavelength selective elements on the surface of the converter layer. In some aspects, one or more circles or one or more polygons are also possible. It would also be conceivable to use the respective “negative” shapes, e.g. holes instead of circles.

It should be mentioned at this point that such a pattern can change across a wafer with a large number of components, as this depends on the necessary color location shift. This means that although components may show the same color location during operation, they may still have a different pattern or a different coverage area.

In some aspects, the wavelength selective mirror covers a portion of the converter layer that is in the range of between 0.1% and 30% of the area of the converter layer. In particular, the area may be divided into different, uniform steps, for example between 0% and 25%. The steps and the individual areas depend on the area of the converter material and the thickness and number of reflector strips. In practice, for example, a fixed number of strips can be provided, the thickness of which is then varied. Alternatively, if the width is fixed, the number of strips can be varied. In this way, for example, the following degrees of coverage can be generated across a wafer or even individual optoelectronic components: 0%, 2%, 5%, 7.5%, 10%, 12.5%, 15% and 20%. Conveniently, in some aspects, the number or thickness does not change across an optoelectronic component, but only between two components.

Another aspect deals with the thickness of components. It has been found that a thin converter layer is sufficient, as this does not significantly influence the overall radiation behavior. By reflecting part of the light back into the converter layer, the effective thickness of the converter layer is increased, so that the probability of conversion increases. In this respect, the thickness of the converter layer is in some aspects in the range from 5 μm to 150 μm, in particular in the range from 10 μm to 50 μm, and is in particular less than 80 μm or 70 μm.

The wavelength-selective mirror preferably transmits light in the yellow color spectrum, i.e. approximately 550 nm to 595 nm, for example. In addition, the wavelength-selective mirror can have a transition range from a high reflectivity to a low reflectivity in a wavelength range between the first wavelength and the second wavelength. In this context, a high reflectivity is above 80% and in particular above 93%. A low reflectivity is in a range of less than 15% and in particular less than 5%.

In some aspects, the converter layer has an organic or ceramic-based inorganic matrix with embedded organic converter material. This is sufficiently temperature resistant to remain stable during the mirror deposition process.

The aforementioned problem is also solved by a method for manufacturing an optoelectronic component. A wafer is provided with a plurality of semiconductor components which are configured to emit light of a first wavelength, a surface of the components and thus also of the wafer being covered by a converter layer. A map of an actual color spectrum of the color emission of the surface of the wafer is created and a local deviation is subsequently determined from a target color spectrum and the map of the actual color spectrum. Correction parameters for the surface of the wafer are then determined from this. The correction parameters determined in this way are used to apply a wavelength-selective mirror for the range of the first wavelength to parts of the converter layer as a function of the correction parameters.

The combination of a thin conversion layer and a partial wavelength-selective mirror according to the invention enables significant chromaticity tracking without any negative influence on the radiation behavior.

In some aspects, the step of providing a wafer comprises providing a substrate. A plurality of semiconductor components configured to emit light of a first wavelength are formed thereon. It is possible to use a separate growth substrate and then re-bond the semiconductor components. In addition, an essentially uniformly thick converter layer is applied to the semiconductor components, in particular by spray coating. The converter layer can have a thickness in the range from 5 μm to 50 μm, in particular in the range from 10 μm to 40 μm, in particular less than 40 μm.

In a further aspect, the map of the actual spectrum is formed by assigning a point on the map to each of the plurality of semiconductor components and determining the actual color spectrum for that point. In other words, a map is formed by recording the actual spectrum of each component on the wafer. The position on the map corresponds to the position of the component on the wafer.

To generate the actual color spectrum, it is proposed in some aspects to generate a luminescence spectrum for each of the plurality of semiconductor components. Optionally, defective semiconductor components and/or semiconductor components with a luminescence below a threshold value can also be identified in this way. These can thus be sorted out at an early stage.

As already mentioned, the map of the actual color spectrum is compared with a target color spectrum. In some aspects, the target color spectrum is also provided in the form of a map, whereby the points on the two maps correspond to each other. In this respect, different points on the map can have different target color values. This makes it possible to define different desired target color values on one wafer. Alternatively, a map of the target color values can also be based at least partially on a map of the actual color values, for example in order to generate the most uniform coverage possible in later steps. This may reduce the complexity of the process.

With the proposed method, an actual color value cannot be shifted in any direction. It is therefore useful in some aspects if the target color spectrum can be derived from a CIE standard color chart using at least one pair of coordinates. A CIE standard colour chart is a standardized tool, which in turn can be converted into other colour charts or standards. In this respect, other standards can also be used instead of the CIE standard color chart and for the purpose of this application, the CIE standard color chart is intended to be synonymous with the other standards.

In some aspects, a pair of coordinates comprises two coordinates, referred to as ex and cy, respectively. In some aspects, the values of the respective coordinates are equal to or greater than the corresponding coordinate values of the pair of a point of the map of the actual color spectrum. In this way, it is ensured that a chromaticity shift is affected in a direction that can be realized by the proposed method.

In one embodiment of the proposed method, in the step of determining correction parameters, a proportion of the area of the wavelength-selective mirror to the total area of the converter layer required for the chromaticity shift is determined. In a detailed aspect, it is proposed to determine, for each point of the map of the actual color spectrum, i.e. each of the plurality of semiconductor components, a proportion of the area of the wavelength selective mirror to the area of the converter layer over the respective semiconductor component.

In some aspects of the proposed principle, the correction parameters are determined from the local deviations by calculating an area of the wavelength-selective mirror to the respective area of the converter layer by simulation with different degrees of coverage.

In some aspects, the step of applying a wavelength selective mirror comprises applying a reflector surface, in particular a uniform reflector surface over the entire wafer. The reflector surface can then be structured to form uncovered and covered portions on the converter layer. This structuring is conveniently carried out using the correction parameters.

In some aspects, it is provided to form at least one reflector strip, in particular a plurality of parallel reflector strips, in particular from 6 to 9 parallel reflector strips on the surface of the converter layer, for example to structure them from the reflector surface. Thus, in addition to several parallel reflector strips, several reflector strips extending perpendicular to these reflector strips can be formed on the surface of the converter layer. Alternatively, in some embodiments, other shapes are also available, e.g. rectangles, squares or other shapes, which are produced on the converter layer using known technologies. In some aspects, the reflector strips are applied parallel and/or perpendicular to each other so that the uncovered areas of the converter layers are arranged in a checkerboard pattern.

A further aspect relates to the size and number of strips. In some aspects, the at least one reflector strip, and in particular the plurality of reflector strips and/or the at least one reflector element, each cover one of the plurality of semiconductor components. For example, the surface of the converter layer of a semiconductor component on the wafer may thus be covered by a plurality of reflector strips or more generally by a plurality of wavelength selective elements.

In some aspects, the reflector strips have at least partially different widths across the wafer, or adjacent reflector strips are spaced apart from each other by different distances across the wafer. The same naturally also applies to other forms of wavelength-selective elements listed in this application.

An area of the applied wavelength selective elements on a semiconductor component of the plurality of semiconductor components may in some aspects be in the range of 0.1% to 50% and in particular less than 30% and in particular in the range of 2% to 20% of the area of the converter layer over that semiconductor component. The area covered by the wavelength selective element thus corresponds to the coverage, which need not be the same as the shadowing, but is often similar to it.

In some aspects, the wave-selective elements comprise or consist of a wavelength-selective mirror DBR [distributed Bragg reflector]. In particular, the elements may be configured to transmit light in the yellow color spectrum, in particular in the range of 550 nm to 600 nm.

In a further step, the process optionally involves separating the wafer to produce a large number of optoelectronic components.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows a sketch of a wafer with several light emitting semiconductor components in a side view as well as two top views as a comparative example for understanding some aspects of the proposed principle;

FIG. 2 shows a sketch of a map of an actual color distribution of a wafer according to FIG. 1 to illustrate some aspects of the proposed principle;

FIG. 3 shows an illustration of an optoelectronic component after fabrication and separation showing some aspects of the proposed principle;

FIG. 4 shows a diagram of the average reflectivity of a wavelength-selective mirror according to the proposed principle at different angles of incidence;

FIG. 5 shows an illustration of local color correction on a wafer to illustrate some aspects of the proposed principle;

FIG. 6 shows an example of color correction for a dot on the wafer surface;

FIG. 7 shows a sketch showing the direction of possible color location corrections on a wafer;

FIG. 8 shows a graph of light emitting component efficiency versus relative color correction for components manufactured according to the proposed principle compared to conventional components;

FIG. 9 shows luminous intensity over the far-field angle for optoelectronic components according to the proposed principle;

FIG. 10 shows the relative color shift is the far-field angle for optoelectronic components according to the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

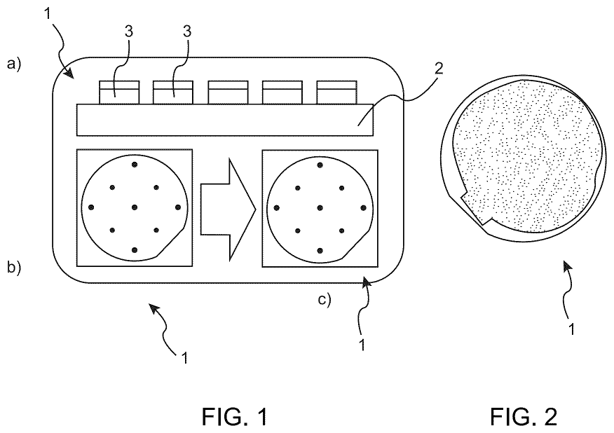

FIG. 1 shows various steps of a process for manufacturing an optoelectronic component. Starting from a growth substrate, a semiconductor layer sequence with an active zone is applied, which is suitably structured in several steps so that a plurality of light-emitting semiconductor components 3 are formed on a substrate 2. The active zone is configured for light emission. The light-emitting semiconductor components generally form a continuous surface during production, but are shown separately in the illustration of sub-figure a) in order to anticipate the subsequent separation step. The light-emitting semiconductor components 3 each have a light-emitting surface 4. In a second step b) and c), this surface is coated with a converter layer 5 over its entire surface, i.e. over the entire wafer, by means of spray coating or another suitable procedure.

The converter layer 5 is applied to the surface of the wafer as evenly as possible and with a constant thickness. It comprises an organic or inorganic ceramic-based matrix in which an organic material is incorporated. The desired color location is generally set via the thickness of the converter layer and the particle concentration within the matrix. However, the converter thickness is not constant everywhere and the amount of converter material within the matrix can also vary. The same generally applies to the layer sequence of the light-emitting semiconductor components, as the layer thicknesses, the doping concentration and other parameters can fluctuate across the wafer, resulting in a different intensity and/or color of the light emitted by the semiconductor components. The wavelength response as well as the different converter thicknesses and phosphor quantity fluctuation thus produce a broad color location distribution, which is shown as an example in FIG. 2.

To correct the color location, it is now proposed to cover a portion of the converter layer with a wavelength-selective mirror. This is designed in such a way that it reflects back the light emitted but not converted by the respective semiconductor component so that it can be absorbed and converted again within the converter layer. Converted light, on the other hand, is transmitted by the mirror. This changes the proportion of converted (e.g. yellow) and unconverted (e.g. blue) light, so that the perceived color shifts slightly. The strength of this color location shift of the optoelectronic component can be adjusted by the size of the covered part.

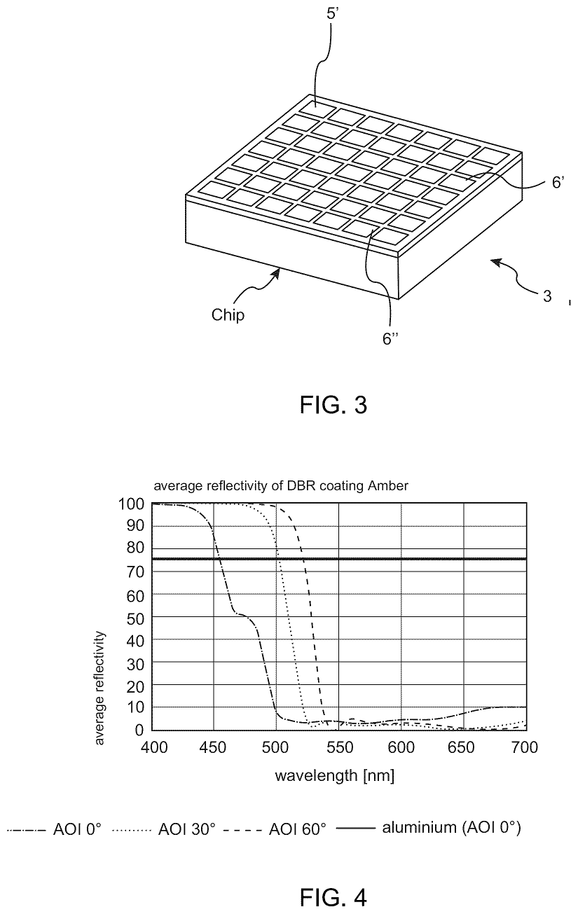

One such embodiment of an optoelectronic component with a converter layer partially covered by a wave-selective element is shown in FIG. 3. As shown in FIG. 3, this is partially provided with a reflector 6. The reflector 6 is a distributed Bragg reflector (DBR). This is a wavelength-selective reflector consisting of alternating thin layers of different refractive indices. The light-emitting component 3 therefore has a converter applied as a flat layer, which is provided with a reflector 6 in some areas. The reflector 6 is applied in parallel reflector strips 6′ and reflector strips 6″ perpendicular to these, so that uncoated converter surfaces 5′ are formed between reflective reflector strips 6′, 6″, which can radiate freely. The uncoated converter surfaces 5′ are thus arranged in a checkerboard pattern.

The shape shown in FIG. 3 can be formed by creating a reflector surface on the converter layer, for example by forming a Bragg mirror. This is then structured over the surface so that the pattern shown in FIG. 3 is formed. The structuring can be carried out chemically, but also by selective mechanical or optical destruction or removal of the mirror. By varying the number of parallel reflective reflector strips 6′, 6″ and by varying their width, the degree of coverage of the converter layer 5 can be varied over a wide range.

FIG. 4 shows the average reflectivity of a DBR mirror as a function of the angle of incidence across different wavelengths. For comparison, aluminum is also shown, which has an essentially constant reflectivity. In the wavelength range of chip emission between approx. 400-350 nm, the mirror has an average reflectivity of almost 100%, even at different angles. Relatively flat incident light beams (AOI=60°, angle relative to the perpendicular to the mirror), which occur rather rarely due to the size of the component, show a decrease in reflectivity, especially between 450 nm and 500 nm. With steeper angles (e.g. AOI=0°), the reflectivity only decreases steeply towards 520 nm. This means that at small angles of incidence (AOI⇐30°) in particular, a large edge steepness and therefore a high selectivity for blue light is achieved. Overall, the difference in wavelength with the same reflectivity and different angles is around 100 nm. In other words, and in relation to the light of the semiconductor element and the converted light, the DBR mirror shows a reflectivity of greater than 95%, almost 100% in the range of less than 450 nm, while its reflectivity for yellow light from 550 nm is less than 10%, both at small and large angles of incidence.

To generate the desired degree of coverage and thus the desired chromaticity shift, the wafer and thus each component is fully characterized after coating the light-emitting surface 4 of the light-emitting component 3 with the converter layer 5.

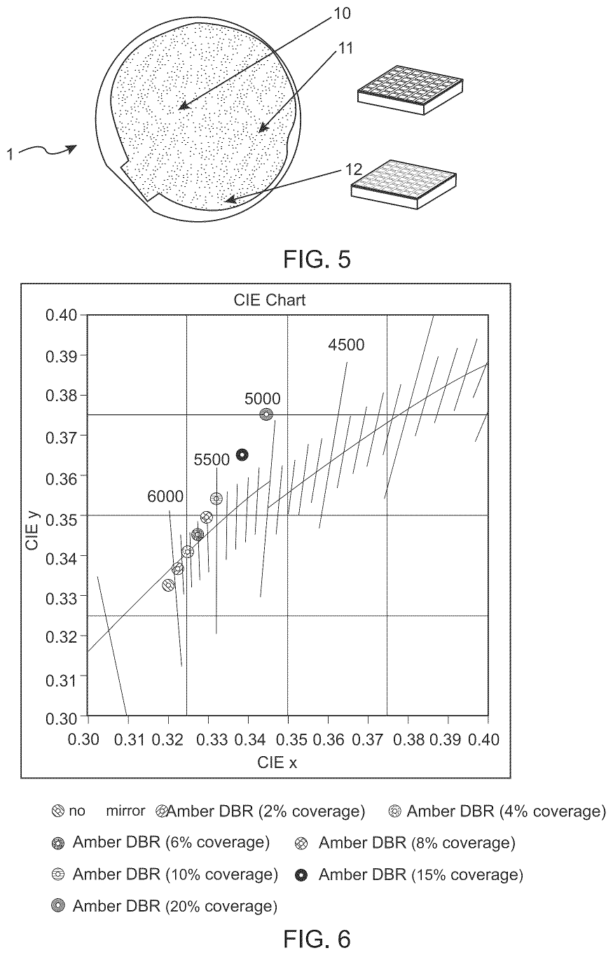

This is done, for example, by recording a spatially resolved luminescence spectrum in which defective components can also be identified immediately. In this way, a spatially resolved color location map is determined, whereby the resolution is technically meaningful and corresponds, for example, to the position of the individual components. In other words, each point on the map corresponds to a component on the wafer for which the actual color value was determined from the spectrum. The result of such a map is shown in FIG. 5 on the left and FIG. 1 on the right.

The deviation, i.e. the difference from a target colour value, is then determined for the wafer precharacterized in this way. It should be mentioned at this point that the target color value can either be constant, but can also be selected depending on the position on the wafer or the actual color value. The latter choice would be useful, for example, if different color locations are to be generated per wafer and components that are close to the desired color value are already identified in this way. In this way, it is also possible to continuously change the coverage on the wafer. Depending on the target color location and the degree of correction or a degree of coverage with a corresponding DBR is calculated. FIG. 6 shows an example of color correction for a point X with the coordinates CIE_X=0.32 and CIE_Y=0.332 in the CIE standard color system. By applying strip-shaped DBR reflectors as described above with 2% coverage to 20% coverage, as can be seen in FIG. 6, the chromaticity coordinates essentially shift towards the yellow/green range at higher coverage.

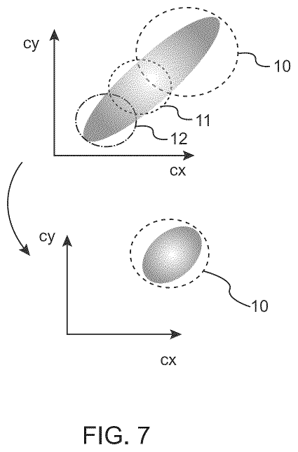

The concept according to the invention reduces the blue component in favor of the amount of converted light. This allows the color location to be shifted in the direction of the converter color location, as shown in FIG. 7. This shift can in principle be determined for each individual component, but also for groups of components on the wafer. With the known degree of coverage, the structure of the wavelength-selective element shown in FIG. 3 can now be generated. As shown here, a chessboard-like pattern is formed on the component. This has the advantage that there is no difference in color perception, which can occur with high degrees of coverage when larger contiguous areas are covered. In the example embodiment, this problem is prevented because covered and uncovered areas alternate periodically.

As the color location only shifts very slightly from component to component in practice, it is possible to either group several adjacent components and provide them with the same coverage and therefore the same structure. This simplifies the manufacturing process.

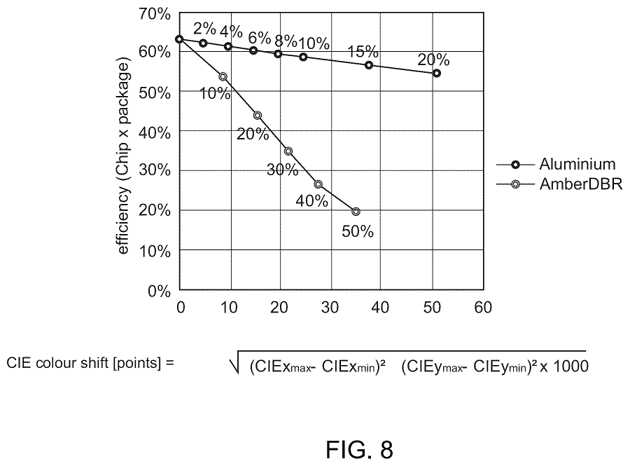

FIG. 8 shows a graph of the efficiency of the optoelectronic component over the relative color correction for a DBR reflector 6 on the one hand and for an aluminum reflector 6 on the other. As can be seen, the loss of efficiency with a DBR reflector 6 is significantly lower than with an aluminum reflector 6. In addition, only a smaller chromaticity shift is possible with aluminum with significantly greater losses at the same time. This is due to the fact that aluminum is not wavelength-selective and therefore generally reduces the intensity of the emitted light. In contrast, the efficiency of a component in which the color location has been shifted according to the proposed principle only decreases by 10%, with a simultaneous shift of the color location by 50 points.

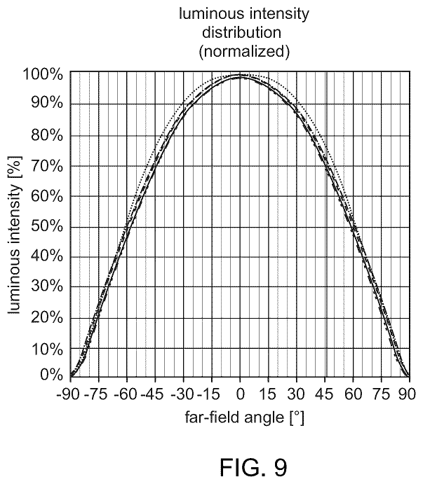

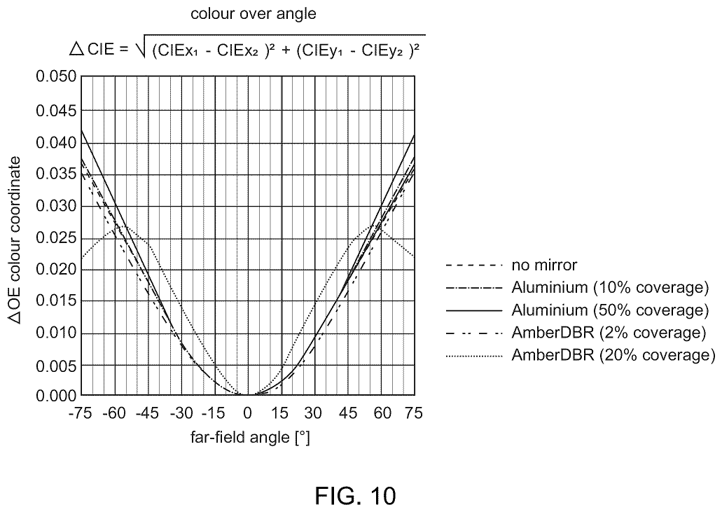

FIGS. 9 and 10 show the luminous intensity and the relative color shift over the far-field angle in degrees [° ], in each case for different degrees of occultation by the reflector 6. There is no significantly different angular dependence for the luminous intensity, even with different degrees of occultation. On the other hand, higher coverage with a wavelength-dependent mirror at higher angles first shows a further change in the chromaticity coordinates, which then reaches its maximum at approx. 550 and decreases again at even higher angles. This can therefore also be seen as an advantage, as the color fidelity with the method presented is still very high, especially for higher degrees of coverage and thus higher color shifts. The coatings considered here are spatially structured and therefore do not significantly impair either the Lambertian far-field characteristic or the color transition.

In the proposed optoelectronic component, a color location shift is therefore achieved by a wavelength-selective element, which is arranged over a portion of the converter layer on the light-emitting component and thus partially covers or shades it. It has turned out to be an advantage that this shading produces a fairly large shift even with low coverage, which also limits the loss of intensity compared to conventional solutions. This makes it possible to achieve a color location correction at wafer level by applying and, if necessary, structuring such an element. The necessary strength of this correction can be determined by first determining the actual color values and comparing them with target color values. As even small amounts of coverage are sufficient for color correction, structuring with simple shapes can be sufficient. By coating with photoresist and subsequent selective oxidation to remove the photoresist for the subsequent production of the wavelength-selective element, groups of components down to individual components can be prepared.

As the behavior often depends on the reactor type used, the color location distributions can also be similar across several wafers. This makes it possible to generate predefined target value maps and corresponding large-area correction structures in order to apply them to a large number of wafers. The yield of components with a preset color value can be significantly increased in this way.

1.-31. (canceled)

32. An optoelectronic component comprising:
at least one semiconductor component configured to emit light of a first wavelength through a surface; and
a converter layer arranged on the surface of the at least one semiconductor component, the converter layer configured to convert the light of the first wavelength into light of a second wavelength,
wherein a portion of the converter layer comprises a wavelength-selective mirror for a range of the first wavelength.

33. The optoelectronic component according to claim 32, wherein the wavelength-selective mirror is at least one reflector strip.

34. The optoelectronic component according to claim 32, wherein the wavelength-selective mirror comprises a plurality of parallel reflector strips and a plurality of reflector strips extending perpendicularly to these reflector strips.

35. The optoelectronic component according to claim 32, wherein the wavelength selective mirror comprises at least one of the following shapes:
one or more rectangles;
one or more squares;
one or more polygons;
one or more circles; or
one or more holes.

36. The optoelectronic component according to claim 32, wherein the portion of the converter layer covered with the wavelength selective mirror is in a range of 2% to 30% of an area of the converter layer.

37. The optoelectronic component according to claim 32, wherein a thickness of the converter layer is in a range from 5 μm to 150 μm.

38. The optoelectronic component according to claim 32, wherein the optoelectronic component comprises a Lambertian radiation behavior.

39. The optoelectronic component according to claim 32, wherein the wavelength-selective mirror comprises a transition region from a high reflectivity to a low reflectivity in a wavelength range between the first wavelength and the second wavelength.

40. The optoelectronic component according to claim 32, wherein the wavelength-selective mirror is configured to transmit light in a yellow color spectrum.

41. The optoelectronic component according to claim 32, wherein the converter layer comprises an organic or ceramic-based inorganic matrix with embedded inorganic converter material.

42. A method for manufacturing an optoelectronic component, the method comprising:
providing a substrate comprising a plurality of semiconductor components configured to emit light of a first wavelength, wherein a surface of the substrate is covered by a converter layer configured to generate light of a second wavelength;
creating a map of an actual color spectrum of a color radiation of the surface of the substrate;
determining a local deviation from a target color spectrum and the map of the actual color spectrum;
determining correction parameters for the surface of the substrate from the local deviations; and
applying a wavelength-selective mirror for a range of the first wavelength to portions of the converter layer as a function of the correction parameters.

43. The method according to claim 42, wherein providing the substrate comprises:
providing a substrate;
forming the plurality of semiconductor components; and
forming a converter layer of substantially uniform thickness by spray coating or by a molding process.

44. The method according to claim 42, wherein the converter layer comprises a thickness in a range from 5 μm to 150 μm.

45. The method according to claim 42, wherein creating the map is conducted in such a way that to each of the plurality of semiconductor components a point on the map is assigned and for this point the actual color spectrum is determined.

46. The method according to claim 42, wherein creating the map comprises:
recording a luminescence spectrum for each of the plurality of semiconductor components; and
optionally identifying defective semiconductor components and/or semiconductor components with a luminescence below a threshold value.

47. The method according to claim 42, further comprising forming the target color spectrum by a map of the target color spectrum, points of which correspond to points of the map of the actual spectrum.

48. The method according to claim 47, wherein the target color spectrum is derivable by at least one pair from a CIE standard chromaticity diagram, wherein each coordinate of the at least one pair from the CIE standard chromaticity diagram is equal to or greater than the corresponding coordinate of the pair of a point of the map of the actual color spectrum.

49. The method according to claim 42, wherein determining the correction parameters comprises determining a proportion of an area of the wavelength-selective mirror of a total area of the converter layer.

50. The method according to claim 42, wherein determining the correction parameters comprises determining a proportion of an area of the wavelength-selective mirror of an area of the converter layer associated with each point of the map of the actual color spectrum.

51. The method according to claim 42, wherein determining the correction parameters is carried out from the local deviations by determining an area of the wavelength-selective mirror to a respective area of the converter layer by simulation calculation with different degrees of coverage.

52. The method according to claim 42, wherein applying the wavelength selective mirror comprises:
applying a reflector uniformly over an entire substrate; and
structuring the reflector to form uncovered and covered areas on the converter layer.

53. The method according to claim 42, wherein applying the wavelength selective mirror comprises forming at least one reflector strip on a surface of the converter layer.

54. The method according to claim 53, wherein the at least one reflector strip is applied on the surface of the converter layer covering one of the plurality of semiconductor components.

55. The method according to claim 53, wherein reflector strips have at least partially different widths across the substrate.

56. The method according to claim 53, wherein the reflector strips are applied parallel and/or perpendicular to one another, so that uncovered areas of the converter layer are arranged in a checkboard pattern.

57. The method according to claim 42, wherein applying the wavelength selective mirror comprises forming a plurality of parallel reflector strips and a plurality of reflector strips extending perpendicular to these reflector strips on a surface of the converter layer.

58. The method according to claim 42, wherein applying the wavelength selective mirror comprises forming several reflector elements in form of rectangles on a surface of the converter layer.

59. The method according to claim 42, wherein an area of the applied wavelength selective mirror over the semiconductor component of the plurality of semiconductor components is in a range of 2 to 50% of an area of the converter layer over the semiconductor component.

60. The method according to claim 42, wherein the wavelength selective mirror comprises a distributed Bragg reflector (DBR).

61. The method according to claim 42, wherein the wavelength selective mirror comprises a transition region from a high reflectivity to a low reflectivity in a wavelength range between the first wavelength and the second wavelength.

62. The method according to claim 42, wherein the substrate comprises a plurality of light emitting components, and wherein the light emitting components are separated after applying the wavelength-selective mirror.
